(19) United States
(12) Patent Application Publication
(10) Pub. No.: US 2024/0071746 A1
(43) Pub. Date: Feb. 29, 2024

(54) PLASMA SURFACE TREATMENT FOR WAFER BONDING METHODS

(71) Applicant: Tokyo Electron Limited, Tokyo (JP)

(72) Inventors: Yu-Hao Tsai, Albany, NY (US); Hojin Kim, Albany, NY (US); Mingmei Wang, Albany, NY (US)

(73) Assignee: Tokyo Electron Limited, Tokyo (JP)

(21) Appl. No.: 17/896,961

(22) Filed: Aug. 26, 2022

(51) Int. Cl. H01L 21/02; H01L 21/18

(52) U.S. Cl. CPC H01L 21/02252; H01L 21/02052; H01L 21/02323; H01L 21/02332; H01L 21/0234; H01L 21/02343; H01L 21/187

(57) ABSTRACT

A method includes providing a first substrate having a first surface and a second substrate having a second surface, where the first surface and the second surface each include a silicon-based dielectric layer, applying hydrogen plasma to form hydrogen-terminated groups on the silicon-based dielectric layer, applying oxygen plasma to oxidize the silicon-based dielectric layer including the hydrogen-terminated groups, applying nitrogen plasma to the oxidized silicon-based dielectric layer, thereby forming a treated silicon-based dielectric layer, rinsing the treated silicon-based dielectric layer, and coupling the first substrate to the second substrate by physically contacting the rinsed and treated silicon-based dielectric layer on the first surface with the rinsed and treated silicon-based dielectric layer on the second surface.

### FIELD OF THE DISCLOSURE

This disclosure relates to microelectronic devices including semiconductor devices, transistors, and integrated circuits, including methods of microfabrication.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area. As the demand for miniaturization, higher speed, and greater bandwidth, as well as lower power consumption and latency has grown recently, there has grown a need for smaller and more creative packaging techniques of semiconductor dies.

Wafer-to-wafer, chip-to-chip, and chip-to-wafer bonding are generally implemented to continue power-performance-area-cost (PPAC) scaling for complex circuits such as are implemented in systems on chip (SOCs). Many bonding techniques utilize oxide-to-oxide bonding adhesion and forming integrated interconnect structures through a hybrid bonding technique that enables interconnections to be formed at the bond interface between two wafers or dies. While methods of implementing the various bonding processes have been generally adequate, they are not entirely satisfactory in all aspects. For example, it may be desirable to perform surface treatment to the substrates (e.g., wafers, chips, etc.) before implementing the bonding process to enhance the chemical adhesion between the substrates.

### SUMMARY

The present disclosure provides various embodiments for performing a series of plasma treatments to semiconductor substrates to be bonded in a process such as hybrid bonding.

One embodiment may include a method for fabricating a semiconductor structure. The method includes providing a first substrate having a first surface and a second substrate having a second surface, where the first surface and the second surface each include a dielectric layer. The method includes treating the first surface and the second surface. The method includes rinsing the first surface and the second surface to hydrolyze the treated dielectric layer. The method further includes coupling the hydrolyzed and treated dielectric layer on the first surface with the hydrolyzed and treated dielectric layer on the second surface. In the present embodiments, the step of treating the first surface and the second surface includes performing a hydrogen plasma treatment to form hydrogen-terminated groups on the dielectric layer, performing an oxygen plasma treatment to oxidize the dielectric layer with the hydrogen-terminated groups, and subsequently performing a nitrogen plasma treatment to the oxidized dielectric layer to form a treated dielectric layer.

The dielectric layer may include a silicon-containing dielectric material. The dielectric layer may include a carbon-containing group, a nitrogen-containing group, or both. For embodiments in which the dielectric layer includes the carbon-containing group, performing the hydrogen plasma treatment forms the hydrogen-terminated groups that include —CH₂. For embodiments in which the dielectric layer includes the nitrogen-containing group, performing the hydrogen plasma treatment forms the hydrogen-terminated groups that include —NH.

The step of performing the oxygen plasma treatment forms a volatile compound. The volatile compound includes HNO, CH₂O, or both.

Another embodiment may include a method for fabricating a semiconductor structure. The method includes providing a first substrate having a first surface and a second substrate having a second surface, where the first surface and the second surface each include a silicon-based dielectric layer. The method includes applying hydrogen plasma to form hydrogen-terminated groups on the silicon-based dielectric layer. The method includes applying oxygen plasma to oxidize the silicon-based dielectric layer including the hydrogen-terminated groups. The method includes applying nitrogen plasma to the oxidized silicon-based dielectric layer, thereby forming a treated silicon-based dielectric layer. The method includes rinsing the treated silicon-based dielectric layer. The method further includes coupling the first substrate to the second substrate by physically contacting the rinsed and treated silicon-based dielectric layer on the first surface with the rinsed and treated silicon-based dielectric layer on the second surface.

The silicon-based dielectric layer includes a carbon-containing dielectric material, a nitrogen-containing dielectric material, or both. The silicon-based dielectric layer includes silicon nitride (SiN), silicon carbonitride (SiCN), silicon oxide (SiO₂), silicon oxynitride (SiON), silicon oxycarbonitride (SiOCN), or combinations thereof. The hydrogen-terminated groups include —NH, —CH₂, or both.

The step of applying the oxygen plasma forms a first compound including —Si—O—Si— groups and a second compound including HNO, CH₂O, or both, in the oxidized silicon-based dielectric layer. The step of applying the nitrogen plasma treatment forms —NO groups in the treated silicon-based dielectric layer. The step of rinsing the first surface and the second surface includes reacting deionized water (DI H₂O) with the —NO groups in the treated silicon-based dielectric layer to form —OH groups. The step of coupling the first substrate to the second substrate includes reacting the —OH groups in the hydrolyzed and treated dielectric layer of the first surface with the —OH groups in the hydrolyzed and treated dielectric layer of the second surface.

The step of coupling the first substrate to the second substrate includes aligning the rinsed and treated silicon-based dielectric layer on the first surface to face the rinsed and treated silicon-based dielectric layer on the second surface. The step of coupling the first substrate to the second substrate includes physically contacting the aligned first surface and second surface. The step of coupling the first substrate to the second substrate further includes subsequently thinning the first substrate, the second substrate, or both.

The first surface and the second surface each further include an interconnect structure disposed adjacent the dielectric layer, and the step of coupling the first substrate to the second substrate includes physically contacting the interconnect structure of the first surface with the interconnect structure of the second surface.

Yet another embodiment may include a method for fabricating a semiconductor structure. The method includes providing a first substrate having a first surface and a second substrate having a second surface, where the first surface and the second surface each include a dielectric feature. The method includes applying surface treatment to the dielectric feature. The method includes coupling the first substrate to the second substrate by physically contacting the hydrolyzed and treated dielectric layer on the first surface with the hydrolyzed and treated dielectric layer on the second surface. In the present embodiments, the step of applying the surface treatment includes applying hydrogen plasma to form hydrogen-terminated groups on the dielectric feature, applying oxygen plasma to oxidize the dielectric feature having the hydrogen-terminated groups, applying nitrogen plasma to the oxidized dielectric feature, thereby forming a treated dielectric feature on the first surface and the second surface, and hydrolyzing the treated dielectric feature.

The hydrogen-terminated groups include —NH, —CH₂, or both. The first surface and the second surface each include a conductive feature adjacent the dielectric feature, and the step of coupling the first substrate to the second substrate further includes aligning the conductive feature of the first surface with the conductive feature of the second surface.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustrations and a further understanding of the various aspects and implementations, and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIGS. 1A and 1B each illustrate a flow chart of an example method for making a semiconductor structure (e.g., a semiconductor package), in accordance with some embodiments.

FIGS. 2A, 3A, 4A, 5A, 6A, 7A, 8A, 9, and 10 each illustrate a three-dimensional perspective view of an example semiconductor structure at intermediate operations of the methods illustrated in the flow charts of FIGS. 1A and/or 1B, in accordance with some embodiments.

FIGS. 2B, 7B, and 8B each illustrate a cross-sectional view of the example semiconductor structure taken along line AA′ of FIGS. 2A, 7A, and 8A, respectively, in accordance with some embodiments.

FIGS. 3B, 3C, 4B, 4C, 5B, 6B, and 8C are each a schematic illustration of chemical reactions occurring in the example semiconductor structure at intermediate operations of the methods illustrated in the flow charts of FIGS. 1A and/or 1B, in accordance with some embodiments.

FIGS. 4D and 5C-5F are each schematic molecular dynamic (MD) simulation result of chemical reactions occurring in the example semiconductor structure at intermediate operations of the methods illustrated in the flow charts of FIGS. 1A and/or 1B, in accordance with some embodiments.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

According to one embodiment, a method of implementing surface treatment on a semiconductor substrate for a substrate bonding process is provided. By performing a series of sequential plasma treatments on a dielectric surface exposed on a semiconductor substrate (e.g., a wafer) before coupling or physically connecting the two wafers (or dies), extent of active oxidation reaction between treated dielectric surfaces may be enhanced and the overall chemical bonding between the semiconductor substrates may be improved.

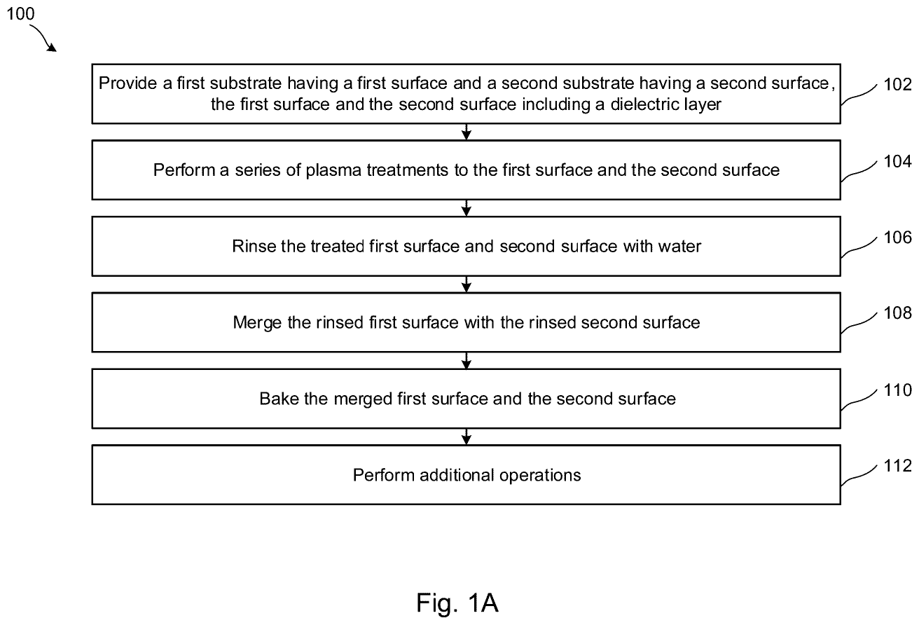

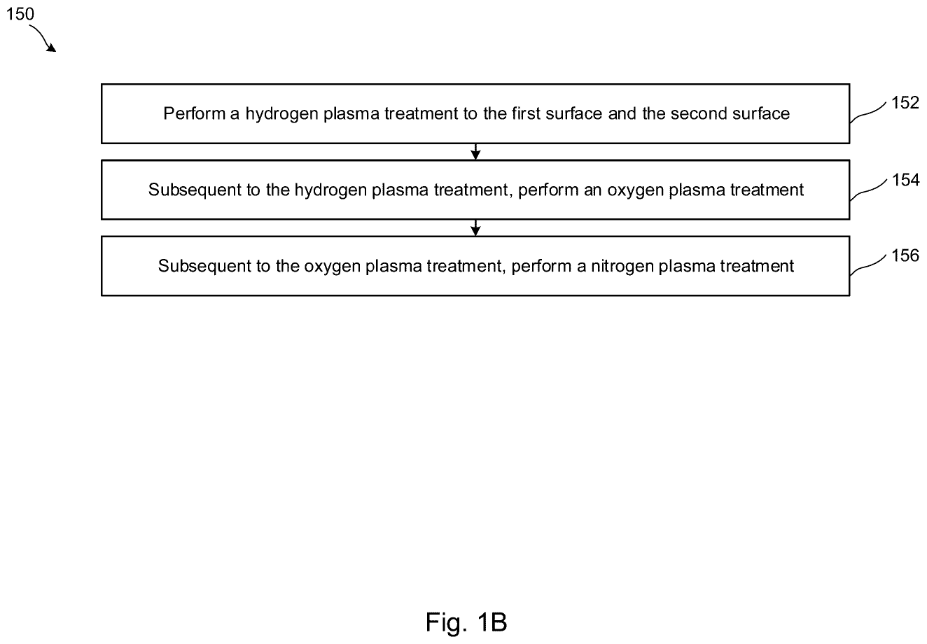

FIG. 1A illustrates a flowchart of an example method 100 for bonding or coupling surfaces of two wafers (e.g., a first wafer 202 and a second wafer 204), a die and a wafer, or two dies to be bonded (e.g., coupled) together to form a semiconductor structure (alternatively referred to as a semiconductor package) 200, according to some embodiments of the present disclosure. FIG. 1B illustrates a flowchart of an example method 150 for implementing the plasma treatments at operation 102 of the method 100, according to some embodiments of the present disclosure. It is noted that the methods 100 and 150 are merely examples and are not intended to limit the present disclosure. Accordingly, it is understood that additional operations may be provided before, during, and after the method 100 of FIG. 1 and/or the method 150 of FIG. 1B, and that some other operations may only be briefly described herein.

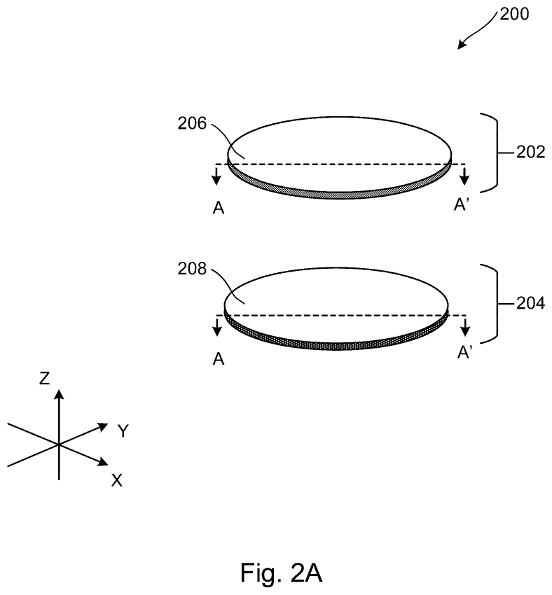

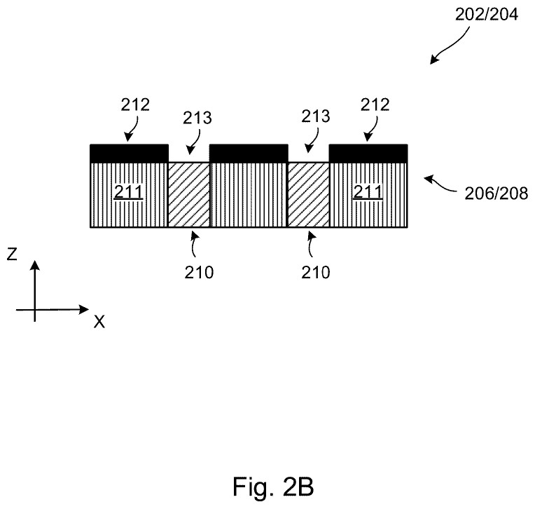

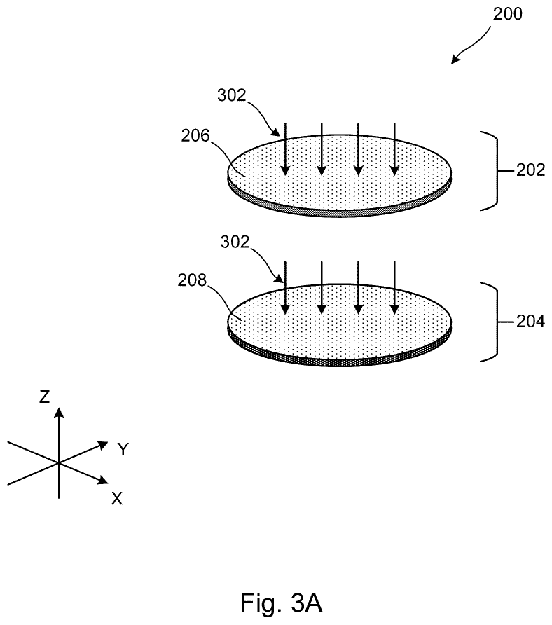

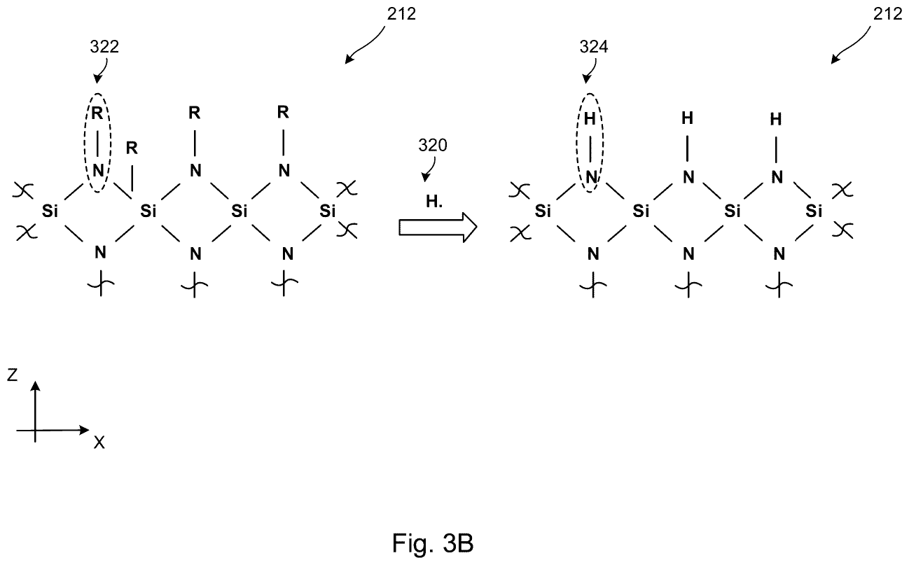

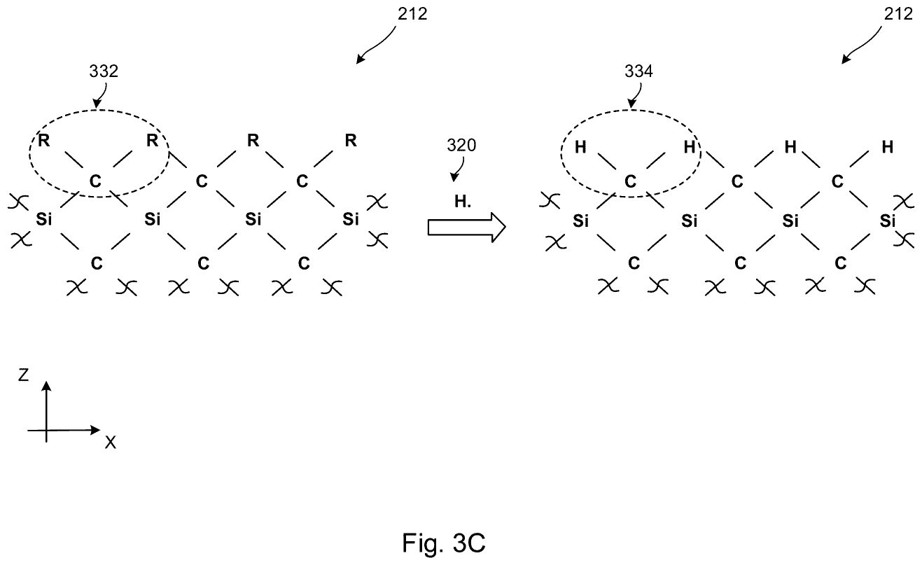

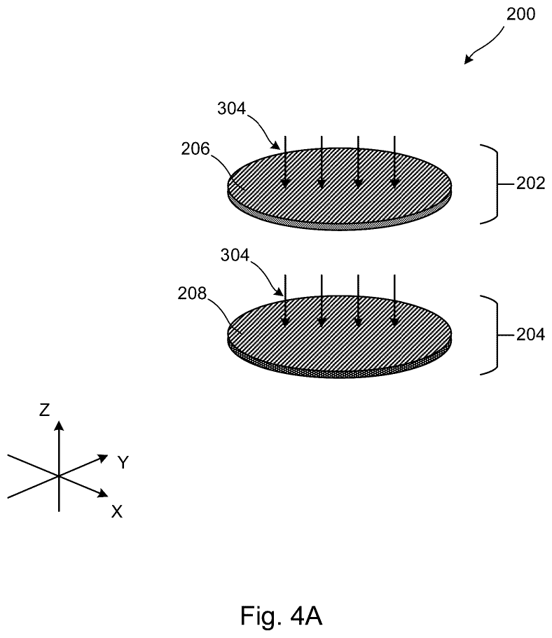

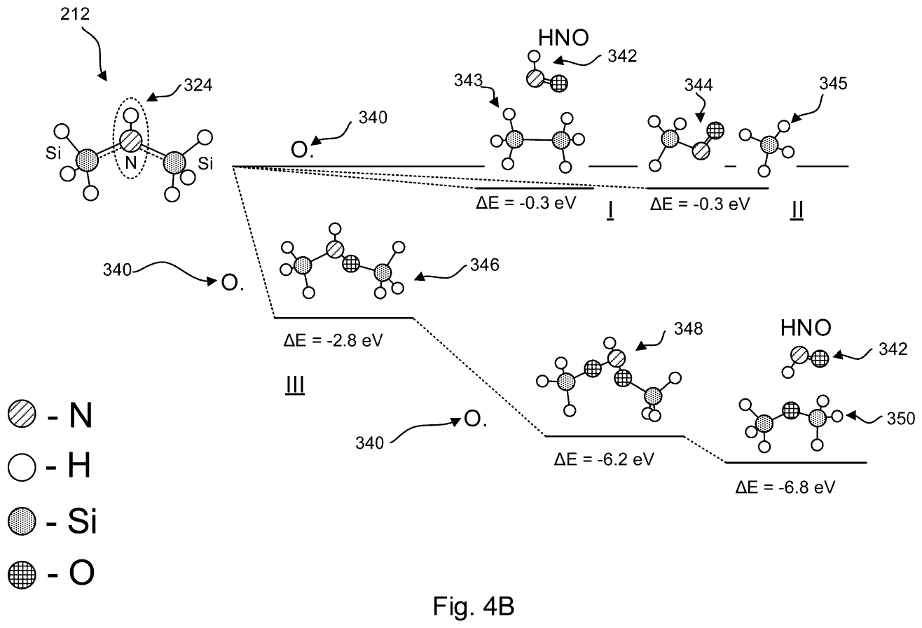

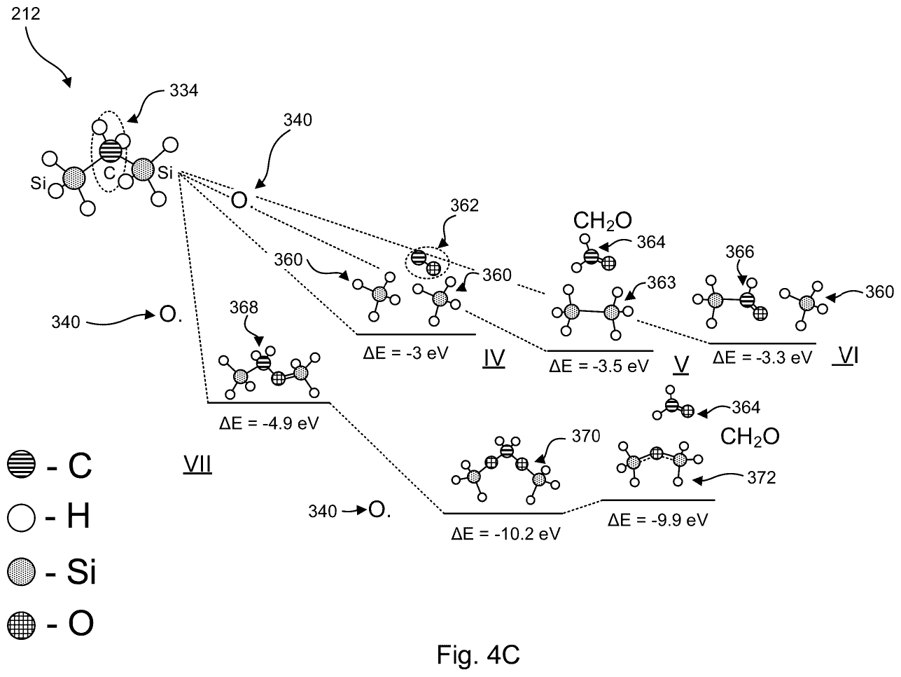

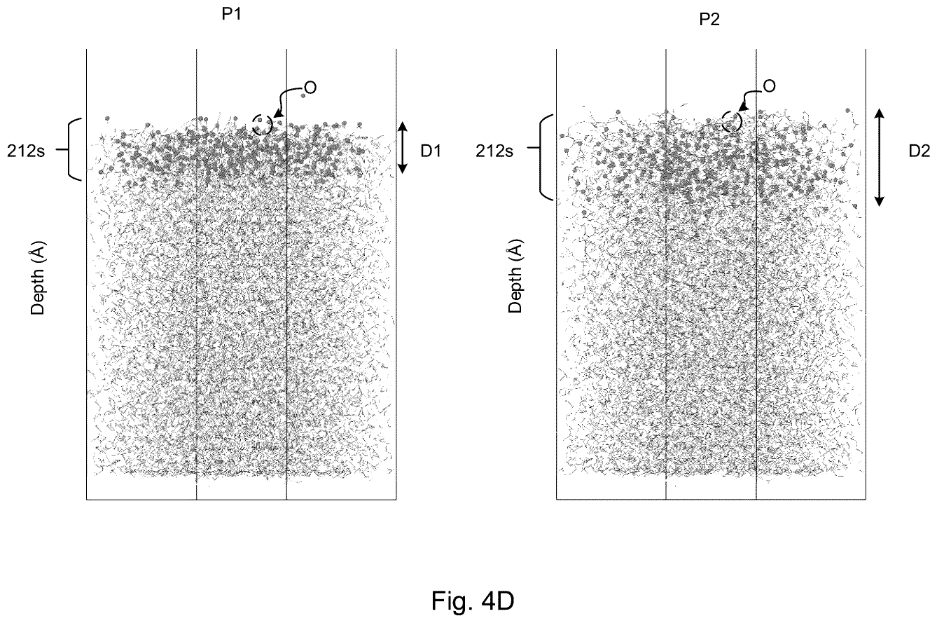

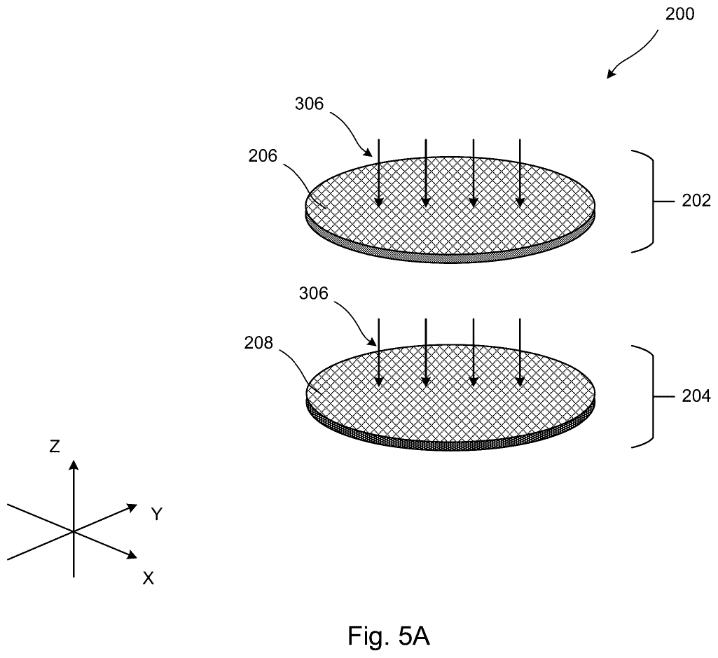

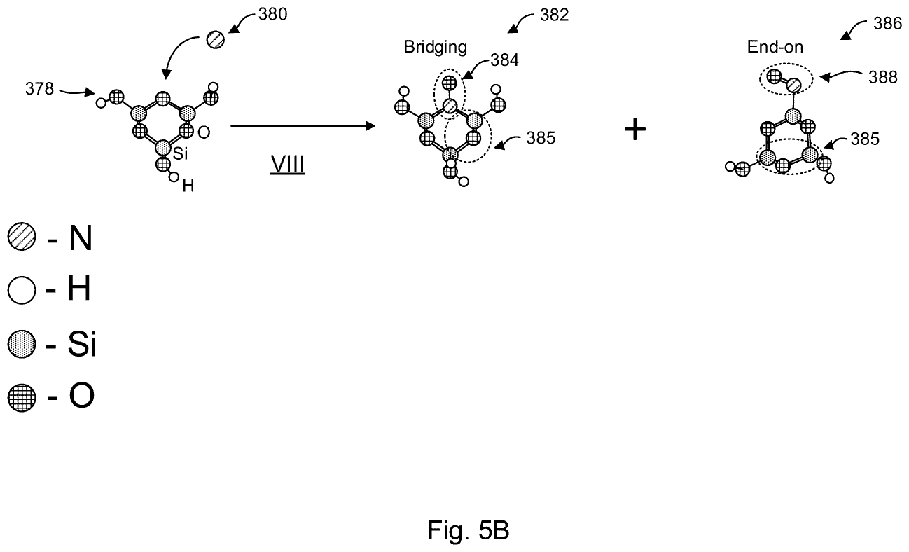

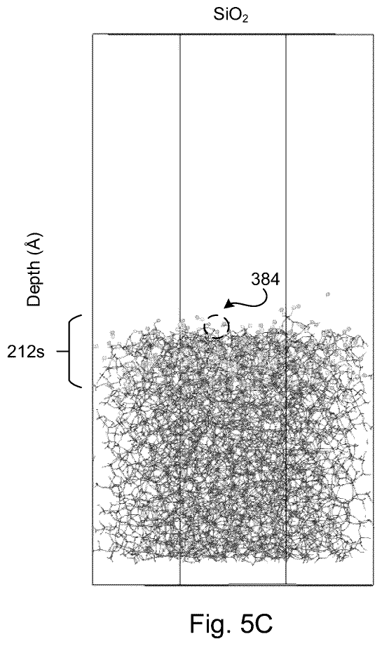

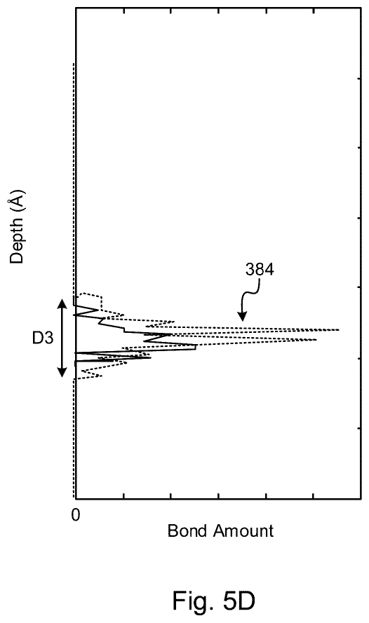

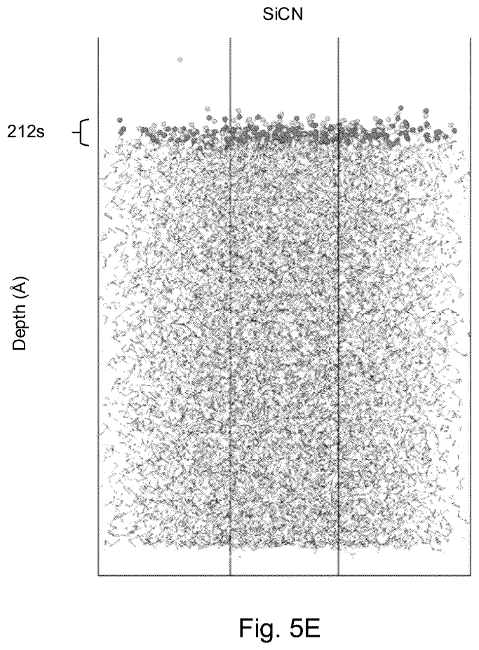

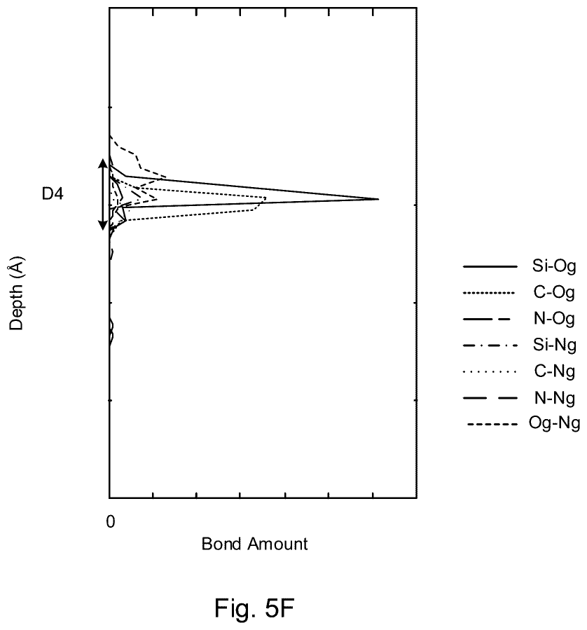

In various embodiments, operations of the methods 100 and 150 may be associated with an example semiconductor structure 200 at various fabrication stages, which will be discussed in further detail below. It should be understood that the semiconductor structure 200 may include a number of other devices such as inductors, fuses, capacitors, coils, etc., while remaining within the scope of the present disclosure. The methods 100 and 150 are illustrated in FIGS. 2A-10 according to some embodiments of the present disclosure. FIGS. 2A, 3A, 4A, 5A, 6A, 7A, 8A, 9, and 10 each illustrate a three-dimensional perspective view of a first wafer (or first substrate) 202 and a second wafer (or second substrate) 204 at intermediate operations of the methods 100 and/or 150. FIGS. 2B, 7B, and 8B each illustrate a cross-sectional view of the first wafer 202 and the second wafer 204 (or collectively, the semiconductor structure 200) taken along line AA′ of FIGS. 2A, 7A, and 8A, respectively. FIGS. 3B, 3C, 4B, 4C, 5B, 6B, and 8C are schematic illustrations of chemical reactions that may occur at a top surface of each of the first wafer 202 and the second wafer 204 at intermediate operations of methods 100 and/or 150. FIGS. 4D and 5C-5F are schematic molecular dynamic (MD) simulation results of chemical reactions occurring at intermediate operations of methods 100 and/or 150. It is noted that the schematic chemical reactions and MD simulation results are merely examples and not intended to limit the present disclosure.

The present disclosure provides a method of treating surfaces of two wafers, e.g., the first wafer 202 and the second wafer 204, before merging or bonding the wafers to form the semiconductor structure 200. Although the depicted embodiments are directed to a wafer-to-wafer bonding configuration, the surface treatment method provided herein may also be applicable for other bonding configurations such as die-to-wafer or die-to-die. Furthermore, the term “substrate” may be used interchangeably with the terms “wafer” and “die” throughout the present disclosure. For simplicity and examples, the semiconductor structure 200 includes the first wafer 202 being bonded to the second wafer 204 in a face-to-face (or front-to-front) configuration with the first wafer 202 being on top of the second wafer 204, i.e., the first wafer 202 corresponds to the top wafer and the second wafer 204 corresponds to the bottom wafer. Other bonding configurations, such as face-to-back (or front-to-back) may also be applicable. In some instances, one or more materials included in the first wafer 202 may be different from those included in the second wafer 204. In some instances, the one or more materials formed for the first wafer 202 may be the same as the second wafer 204.

Referring to FIGS. 1A, 2A, and 2B, the method 100 at operation 102 provides the first wafer 202 having a first surface 206 and the second wafer 204 having a second surface 208. In some instances, the first surface 206 and the second surface 208 may each be a front side of their corresponding wafers. In some instances, one of the first surface 206 and the second surface 208 may be a back side of their corresponding wafers.

The wafers 202 and 204 may each be considered a substrate that includes a semiconductor material, such as a bulk semiconductor, a semiconductor-on-insulator (SOI), or the like, which may be doped (e.g., with a p-type or an n-type dopant) or undoped. The substrate may be or correspond to a respective wafer (e.g., 202 or 204), such as a silicon wafer. Generally, an SOI includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In some embodiments, the wafers 202 and 204 differ in composition.

In some embodiments, referring to FIGS. 2B and 2C, the wafers 202 and 204 each include a number of device features (e.g., transistors, diodes, resistors, etc.; not depicted separately for the sake of clarity) and a number of interconnect structures (alternatively referred to as conductive features) 210 formed over the device features. The interconnect structures 210 are configured to electrically connect the device features to one another so as to form an integrated circuit, which can function as a logic device, a memory device, an input/output device, or the like. The interconnect structures 210 may include horizontal interconnect structures, such as metal lines, and vertical interconnect structures, such as vias. In some embodiments, the interconnect structures 210 each include a conductive layer comprising any suitable conductive material, such as Cu, Al, W, Ru, other suitable materials, or combinations thereof. In some embodiments, the interconnect structures 210 each include the conductive layer over a barrier layer, which may include Ti, Ta, TiN, TaN, other suitable materials, or combinations thereof.

In the depicted embodiments, the interconnect structures 210 are embedded in a dielectric layer 211, which may be a passivation layer. As shown in FIG. 2B, the dielectric layer 211 can be around or surround the sidewall and bottom of the interconnect structures 210. The dielectric layer 211 may exposes the top surface of the interconnect structures 210. The dielectric layer 211 may extend at least from the bottom of the interconnect structures 210 and along sidewalls of the interconnect structures 210. The top surface of the interconnect structures 210 may be substantially even or slightly recessed with respect to a plane of the top surface of the dielectric layer 211. The interconnect structures 210 may be formed in any suitable process, such as one or more damascene processes.

In the present embodiments, the wafers 202 and 204 each further include a dielectric layer (alternatively referred to as a dielectric feature) 212 over the dielectric layer 211 and adjacent the interconnect structures 210. In some embodiments, the dielectric layer 212 is configured to accommodate fusion of the first surface 206 to the second surface 208. The dielectric layer 212 may sometimes be referred to as a bonding layer. In some embodiments, the dielectric layer 212 is formed as a blanket layer over the dielectric layer 211 and the interconnect structures 210, and openings are subsequently formed in the dielectric layer 212 to expose the top surface of the interconnect structures 210. The dielectric layer 212 may be formed or deposited using at least one suitable deposition technique, such as chemical vapor deposition (CVD), flowable CVD (FCVD), atomic layer deposition (ALD), spin coating, other suitable techniques, or combinations thereof.

In some embodiments, the dielectric layer 212 includes a low-k (e.g., having a dielectric constant k less than that of silicon oxide, or SiO₂, which is about 3.9) dielectric material. In some embodiments, the dielectric layer 212 includes more than one type of dielectric materials, such that dielectric materials of different compositions are exposed on the first surface 206 and/or the second surface 208. In the present embodiments, the dielectric layer 212 includes one or more silicon-based (or silicon-containing) dielectric materials, such as silicon nitride (SiN), silicon carbonitride (SiCN), silicon oxide (SiO₂), silicon oxynitride (SiON), silicon oxycarbonitride (SiOCN), other dielectric materials, or combinations thereof. In some embodiments, the silicon-based dielectric materials include carbon (C), nitrogen (N), oxygen (O), or combinations thereof.

In some embodiments, the top surface of the interconnect structures 210 is recessed with respect to the top surface of the dielectric layer 212 to form a trench 213, as depicted in FIG. 2B. In this regard, the dielectric layer 212 protrudes from the top surface of the dielectric layer 211 by a predetermined height configured for the fabrication/formation/manufacturing process of the semiconductor structure 200, such as about 1 nm to about 10 nm, among others. In this instance, a depth of the trench 213 for the top surface of the interconnect structures 210 may correspond to a thickness of the dielectric layer 212. At this stage, the interconnect structures 210 may be coplanar, or substantially coplanar, with the top surface of the dielectric layer 211 below the dielectric layer 212.

In some embodiments, the wafers 202 and 204 are merged (or coupled) by bonding (through a hybrid bonding process, for example) the interconnect structures 210 and the dielectric layer 212 of the first surface 206 with the interconnect structures 210 and the dielectric layer 212 of the second surface 208, respectively. In the depicted embodiments, the dielectric layer 212 is formed on the front side of the first wafer 202 and the second wafer 204. In some instances, the dielectric layer 212 may also be formed on the backside of the first wafer 202 and/or the second wafer 204.

Referring to FIG. 1A, the method 100 at operation 104 proceeds to performing a series of plasma surface treatments to the first surface 206 and the second surface 208 in preparation for the subsequent merging process. In the present embodiments, performing the series of plasma treatments is implemented by the method 150 as depicted in FIGS. 1B and 3A-5F.

Referring to FIGS. 1B and 3A-3C, the method 150 at operation 152 performs a hydrogen plasma treatment 302 to the first surface 206 and the second surface 208. In the present embodiments, the hydrogen (H₂) plasma treatment 302 is configured to introduce hydrogen-terminated groups to the dielectric layer 212 exposed on the first surface 206 and the second surface 208, thereby chemically modifying the dielectric layer 212. In the present embodiments, the hydrogen-terminated groups modify the dielectric layer 212 such that the tendency for forming a more oxidized dielectric layer 212 (or portions thereof) on the first surface 206 and second surface 208 during subsequent plasma treatments is improved.

Depending on the specific composition of the dielectric layer 212, parameters of the hydrogen plasma treatment 302 may be tuned to ensure appropriate conditions are met for the chemical reactions to occur and/or to maximize the yield of the chemical reactions. For instance, the power of the hydrogen plasma may be about 5 W to about 1000 W, the pressure of the hydrogen gas used to form the plasma may be about 50 mTorr to about 500 mTorr, and the temperature may be about 100 degrees Celsius to about 200 degrees Celsius. These parameters are merely examples and do not limit the present embodiments as such. In some embodiments, any hydrogen molecules adsorbed at the surface of the dielectric layer 212 dissociate during the subsequent plasma treatment(s).

For embodiments in which the dielectric layer 212 includes a silicon-and-nitrogen-containing dielectric material, such as silicon nitride (SiN or Si₃N₄) and silicon oxynitride (SiON), referring to FIG. 3B, hydrogen radicals (H·) 320 imparted by the hydrogen plasma treatment 302 react with —NR groups 322 of the dielectric layer 212 to form —NH groups 324 at the surface of the dielectric layer 212, where R may be any suitable groups consistent with the composition of the dielectric layer 212. For embodiments in which the dielectric layer 212 includes a silicon-and-carbon-containing dielectric material, such as silicon carbonitride (SiCN) and silicon oxycarbonitride (SiOCN), referring to FIG. 3C, hydrogen radicals 320 react with —CR₂ groups 332 of the dielectric layer 212 to form —CH₂ groups 334 at the surface of the dielectric layer 212, where R may be any suitable groups consistent with the composition of the dielectric layer 212. In the present embodiments, R does not include H alone but may include, for example, Si, O, C, other suitable groups, or combinations thereof. In the present embodiments, —NR groups 322, —NH groups 324, —CR₂ groups 332, and —CH₂ groups 334 are bonded to at least one Si atom in the dielectric layer 212. In some instances, referring to both FIGS. 3B and 3C, the groups present at the surface of the dielectric layer 212 may differ from those present in the bulk of the dielectric layer 212 in composition.

In some embodiments, reactions producing —NH groups 324 and —CH₂ groups 334 are independent of each other and may occur concurrently or separately depending on the specific composition of the dielectric layer 212. For instances, if the dielectric layer 212 is free, or substantially free, of any silicon-and-carbon-containing dielectric materials, only the reaction depicted in FIG. 3B would occur. If the dielectric layer 212 is free, or substantially free, of any silicon-and-nitrogen-containing dielectric materials, only the reaction depicted in FIG. 3C would occur. If the dielectric layer 212 includes both a silicon-and-nitrogen-containing dielectric material and a silicon-and-carbon-containing dielectric material, then reactions depicted in both FIGS. 3B and 3C may occur. It is noted that the XZ plane in which the dielectric layer 212 is depicted in FIGS. 3B and 3C is for illustration purposes only and is not intended to limit the embodiments of the present disclosure as so.

In some instances, the hydrogen plasma treatment 302 may also create metal hydride at the first surface 206 and the second surface 208. For example, hydrogen plasma may form Cu—H bonds at the top surface of the interconnect structures 210. By adjusting various parameters of the hydrogen treatment 302, the impact of Cu—H to the performance of the resulting semiconductor structure 200 may be reduced or minimized. Alternatively, portions of the first surface 206 and second surface 208 including the interconnect structures 210 may be protected (e.g., using a mask, among other materials/covers) during the hydrogen plasma treatment 302 and/or any subsequent plasma treatment(s).

Referring to FIGS. 1B and 4A-4D, the method 150 at operation 154 subsequently performs an oxygen plasma treatment 304 to the first surface 206 and the second surface 208. In the present embodiments, the oxygen (O₂) plasma treatment 304 is configured to oxidize the dielectric layer 212 (or portions thereof), thereby further modifying the first surface 206 and second surface 208.

In the present embodiments, oxygen radicals (O·) 340 produced by the oxygen plasma treatment 304 react with the dielectric layer 212 to substitute the N and/or C atoms, thereby oxidizing the surface of the dielectric layer 212 in the process. In other words, the oxygen plasma treatment 304 removes the N and/or C atoms in the —NH groups 324 and/or the —CH₂ groups 334, respectively, to form —Si—O— (or —Si—O—Si—) groups in the dielectric layer 212, which then react with nitrogen radicals (N·) to form —NO groups during the subsequent plasma treatment. Importantly, terminating the nitrogen- and the carbon-containing groups with H atoms during the hydrogen plasma treatment 302 lowers the thermodynamic barrier of removing the N and/or C atoms from the dielectric layer 212 during the oxygen plasma treatment 304, leading to a greater extent of oxidation of the surface of the dielectric layer 212.

FIGS. 4B and 4C illustrate various reaction schemes for oxidizing the dielectric layer 212 (or portions thereof) that includes the —NH groups 324 and the —CH₂ groups 334, respectively. It is noted that the various reaction schemes illustrated in FIGS. 4B and 4C are each denoted with a change in energy state, ΔE, that corresponds to the thermodynamic drive of each scheme, where the schemes with more negative ΔE are more thermodynamically stable, yielding a greater amount of reaction product(s). In the present disclosure, the values of ΔE are determined based on the density functional theory (DFT) calculation of small molecules similar to the compounds illustrated herein and should therefore be taken as approximate, rather than exact, values for comparison purposes only.

Referring to FIG. 4B, the oxidation of the dielectric layer 212 containing the —NH groups 324 may proceed in at least one of Schemes I-III. With respect to Scheme I, the oxygen radicals 340 react with the N atoms in the dielectric layer 212 to form a volatile compound, HNO 342 and a —Si—Si-containing compound 343. In this regard, the oxygen radicals 340 scavenge the N atoms from the surface of the dielectric layer 212 by forming HNO 342, which is subsequently removed. With respect to Scheme II, the oxygen radicals 340 react with the N atoms in the dielectric layer 212 to form a —Si—N═O-containing compound 344 and a Si-containing compound 345. With respect to Scheme III, a first oxygen radical 340 reacts with the dielectric layer 212 to form a —Si—NH—O—Si-containing compound 346, thereby oxidizing the dielectric layer 212 (or portions thereof). Subsequently, a second oxygen radical 340 may further oxidize the —Si—NH—O—Si-containing compound 346 to form a —Si—O—NH—O—Si-containing compound 348, a —Si—O—Si-containing compound 350, and HNO 342. In the present embodiments, Schemes I and II demonstrate similar values of ΔE, while Scheme III demonstrates a ΔE that is approximately one order of magnitude larger (in magnitude) than both Schemes I and II, indicating that Scheme III is more thermodynamically stable (or favorable) and that the products of Scheme III may dominate in quantity over those of Schemes I and II. In some embodiments, the interaction between the oxygen radicals 340 and the dielectric layer 212 proceeds according to more than one of Schemes I-III at various reaction rates, depending on their respective values of ΔE.

Similarly, referring to FIG. 4C, the oxidation of the dielectric layer 212 containing —CH₂ groups 334 may proceed in at least one of Schemes IV-VII. With respect to Scheme IV, the oxygen radicals 340 react with the C atoms in the dielectric layer 212 to form a radical CO. 362 and a Si-containing compound 360, which may be similar to the Si-containing compound 345. With respect to Scheme V, the oxygen radicals 340 react with the C atoms in the dielectric layer 212 to form a volatile compound CH₂O 364 and a —Si—Si-containing compound 363, which may be similar to the —Si—Si-containing compound 343. In the present embodiments, the oxygen radicals 340 scavenge the C atoms from the surface of the dielectric layer 212 by forming CH₂O 364, which is subsequently removed. With respect to Scheme VI, the oxygen radicals 340 react with the dielectric layer 212 to form a —Si—CH═O-containing compound 366 and the Si-containing compound 360. With respect to Scheme VII, a first oxygen radical 340 reacts with the dielectric layer 212 to form a —Si—CH₂—O—Si-containing compound 368, thereby oxidizing the dielectric layer 212 (or portions thereof). Subsequently, a second oxygen radical 340 may further oxidize the —Si—CH₂—O—Si-containing compound 368 to form a —Si—O—CH₂—O—Si-containing compound 370, a —Si—O—Si-containing compound 372, which may be similar to the —Si—O—Si-containing compound 350, and CH₂O 364. In the present embodiments, while all being negative, the magnitude of ΔE of Scheme VII is greater than the magnitude of ΔE of Schemes IV-VI, indicating that Scheme VII is more thermodynamically stable (or favorable). In some embodiments, the interaction between the oxygen radicals 340 and the dielectric layer 212 proceeds according to more than one of Schemes IV-VII at various reaction rates, depending on their respective values of ΔE.

In the present embodiments, the volatile compound HNO 342 formed by one or more of Schemes I-III and the volatile compound CH₂O 364 formed by one or more of Schemes IV-VII are subsequently removed from the dielectric layer 212 after performing the oxygen plasma treatment 304. Importantly, the presence of —NH groups 324 and —CH₂ groups 334 obtained from the hydrogen plasma treatment 302 increases the thermodynamic drive (or lowers the thermodynamic barrier) for substituting the N and/or C atoms with O atoms (from the oxygen radicals 340), thereby increasing the amount (or concentration) of O atoms, and consequently the amount of —Si—O—Si— bonds, incorporated in the dielectric layer 212. In other words, implementing the hydrogen plasma treatment 302 and the oxygen plasma treatment 304 in sequence improves the extent of oxidation of the dielectric layer 212, which may be measured in the thickness of the oxidized surface in the dielectric layer 212, according to some embodiments of the present disclosure.

Various parameters of the oxygen plasma treatment 304 may be adjusted to further increase a thickness of oxidized surface 212s of the dielectric layer 212. For example, referring to FIG. 4D, which illustrates variations in concentration of O atoms as a function of depth (or thickness) measured from the surface of the wafers 202 and 204, increasing the power of the oxygen plasma from P1 to P2 increases the thickness of the oxidized surface 212s of the dielectric layer 212 from D1 to D2. It is noted that for purposes of illustration, the extent of oxidation is represented by the concentration of O atoms arising from, for example, the —Si—NH—O—Si-containing compound 346, the —Si—O—NH—O—Si-containing compound 348, the —Si—O—Si-containing compound 350, —Si—CH₂—O—Si-containing compound 368, the —Si—O—CH₂—O—Si-containing compound 370, the —Si—O—Si-containing compound 372, other suitable products of one or more of Schemes I-VII, or combinations thereof. In some examples, the power P2 may be twice as much as the power P1. In the depicted embodiments, the dielectric layer 212 includes oxidized silicon carbonitride (SiCN).

Referring to FIGS. 1B and 5A-5F, the method 150 at operation 156 subsequently performs a nitrogen plasma treatment 306 to the first surface 206 and the second surface 208. In the present embodiments, referring to FIG. 5B, nitrogen radicals (N·) 380 produced by the nitrogen plasma treatment 306 react with a —Si—O—Si-containing compound (e.g., a silicon-containing oxide) 378 of the oxidized dielectric layer 212 via a bridging mechanism to form a compound 382 that includes —NO groups 384 and —Si—O—Si— groups 385. In some embodiments, the nitrogen radicals 380 react with the —Si—O—Si-containing compound 378 of the oxidized dielectric layer 212 via an end-on mechanism to form a compound 386 that includes —N═O groups 388. As depicted herein, the reaction Scheme VIII for forming —NO groups 384 may be characterized by a negative ΔE value, indicating that the reaction (i.e., the bridging mechanism) is thermodynamically stable (or favorable).

In the present embodiments, by increasing the amount of O atoms in the —Si—O—Si-containing compound 378, which is achieved by the sequential implementation of the hydrogen plasma treatment 302 and the oxygen plasma treatment 304, the amount of —NO groups 384 (and/or —N═O groups 388) formed by the nitrogen plasma treatment 306 is also increased, leading to more —OH groups formed at a subsequent hydrolysis process and consequently stronger chemical bond between the wafers 202 and 204 during a subsequent coupling process. Additionally, the increased amount of —NO groups 384 resulting from the sequential implementation of the hydrogen plasma treatment 302 and the oxygen plasma treatment 304 renders the first surface 206 and the second surface 208 more hydrophilic than if the oxygen plasma treatment 304 was implemented without the hydrogen plasma treatment 302. Accordingly, the sequential plasma treatments provided herein may be generally applied during fabrication processes in which modifications of surface chemistry resulting in more hydrophilic properties are desired.

FIGS. 5C-5F collectively demonstrate an increase in the amount of —NO groups 384 formed at the surface 212s of the dielectric layer 212 following the nitrogen plasma treatment 306. Referring to FIGS. 5C and 5D, which correspond to an embodiment of the oxidized dielectric layer 212 including silicon oxide (SiO₂), an increase in the concentration of —NO groups 384 after undergoing the nitrogen plasma treatment 306 is observed at the surfaces 212s. The profile shown in FIG. 5D indicates a distribution of the —NO groups 384 over a thickness D3 of about 20 Å at the surface 212s. Referring to FIGS. 5E and 5F, which correspond to an embodiment of the dielectric layer 212 including silicon carbonitride (SiCN), an increase in the concentration of —NO groups 384 after undergoing the nitrogen plasma treatment 306 is also observed at the surfaces 212s, and such concentration is distributed over a thickness D4 of less than about 20 Å. It is noted that FIGS. 5D and 5F are not drawn to scale and are depicted for illustration purposes only.

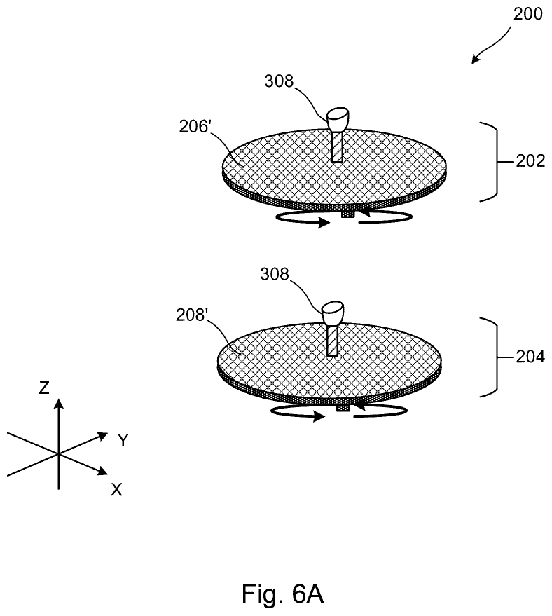

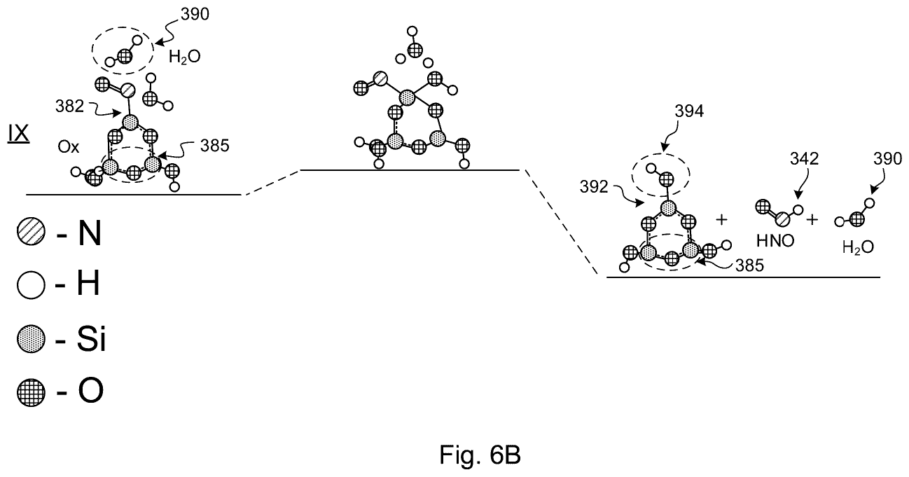

Thereafter, referring to FIGS. 1A, 6A, and 6B, the method 100 proceeds from operation 104 to operation 106 and performs a rinsing process 308 to the first surface 206 and the treated second surface 208, resulting in a treated dielectric layer 212′. In the present embodiments, the rinsing process 308 is performed by applying deionized (DI) water to the first surface 206 and the second surface 208 as depicted in FIG. 6A.

As shown in Scheme IX of FIG. 6B, the compound 382 produced by the nitrogen plasma treatment 306 reacts with H₂O 390 in a hydrolysis process (i.e., hydrolyzing the compound 382 with H₂O 390) to form a compound 392 that includes —Si—O—Si— groups 385 and hydroxide —OH groups 394, as well as products such as HNO 342 and H₂O 390, which may be subsequently removed. In other words, H₂O 390 breaks one or more chemical bonds in the compound 382 to form —OH groups 394, thereby hydrolyzing the dielectric layer 212 (or portions thereof). In the present embodiments, increasing the amount of —NO groups 384 at the surface of the dielectric layer 212 increases the amount of —OH groups 394 formed during the rinsing process 308, which in turn increases the strength of chemical bonding between the first surface 206 and the second surface 208 during the subsequent coupling process.

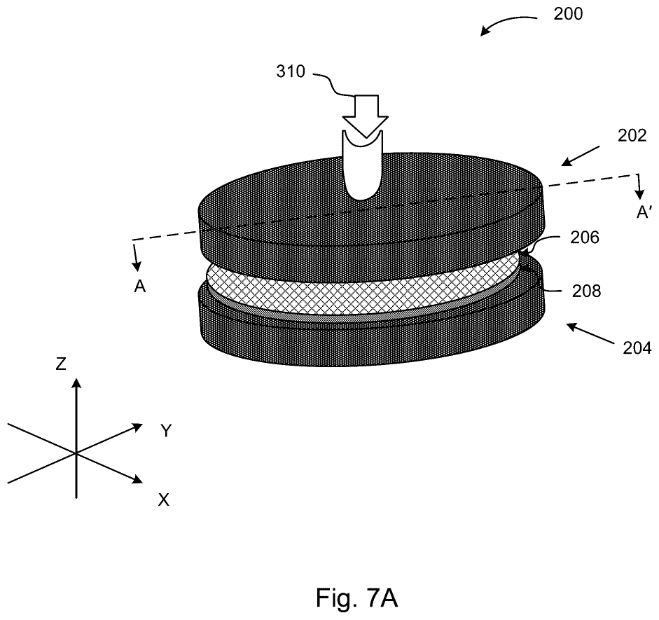

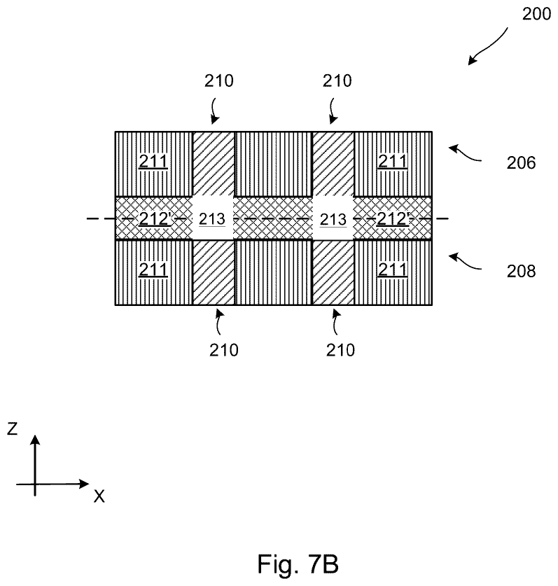

Referring to FIGS. 1A, 7A, and 7B, the method 100 at operation 108 merges or couples the wafers 202 and 204 to form the semiconductor structure 200. As shown in FIG. 7A, the first wafer 202 may be flipped or inverted (e.g., rotated 180 degrees) to engage with the second wafer 204 in a face-to-face configuration during an alignment process 310. In the depicted embodiment, the first surface 206 of the first wafer 202 is positioned to face downward or towards the second surface 208 of the second wafer 204, which is positioned to face upward. In some instances, the second wafer 204 may be flipped instead of the first wafer 202. For simplicity and examples herein, referring to FIG. 7B, the first wafer 202 includes the first surface 206 having at least the treated dielectric layer 212′ and the interconnect structures 210, and the second wafer 204 includes the second surface 208 having at least the treated dielectric layer 212′ and the interconnect structures 210.

The wafers 202 and 204 may be coupled by any suitable process, such as by a hybrid bonding process. In this regard, the alignment process 310 may be implemented by positioning the interconnect structures 210 to directly face the interconnect structures 210 and positioning the treated dielectric layer 212′ exposed on the first surface 206 to directly face the treated dielectric layer 212′ exposed on the second surface 208. In some instances, the alignment process 310 causes the sidewalls of the interconnect structures 210 on the wafers 202 and 204 to be coplanar or substantially coplanar along a common vertical plane along the Z axis.

When the wafers 202 and 204 are aligned, the treated dielectric layer 212′ exposed on the first surface 206 may physically contact, couple, or interconnect with the treated dielectric layer 212′ exposed on the second surface 208. By applying heat and/or pressure (e.g., during physical contact between the treated dielectric layer 212′ of the first surface 206 and the second surface 208, respectively), the wafers 202 and 204 may be coupled/bonded/interconnected. The pressure applied may comprise a pressure of less than about 30 MPa, and the heat applied may comprise an anneal process at a temperature of about 100 degrees Celsius to about 500 degrees Celsius, as examples, although alternatively, other amounts of pressure and heat may be used for the hybrid bonding process. The hybrid bonding process may be performed in a N₂ environment, an Ar environment, a He environment, an (about 4% to about 10%) H₂/(about 90% to about 96%) inert gas or N₂ environment, an inert-mixing gas environment, other types of environments, or combinations thereof. As a result, the wafers 202 and 204 (e.g., the first surface 206 and the second surface 208) may be coupled based on the physically contacting at least the treated dielectric layer 212′.

In some embodiments, the bond between the wafers 202 and 204 includes non-metal-to-non-metal bonds or metal-to-metal bonds. A portion of the hybrid bonding process may comprise a fusion process that forms the non-metal-to-non-metal (e.g., dielectric-to-dielectric) bonds, and a portion of the hybrid bonding process may comprise a copper-to-copper bonding process that forms the metal-to-metal bond, for example. The term “hybrid” refers to the formation of the two different types of bonds (e.g., between the treated dielectric layer 212′ of the wafers 202 and 204 and between the interconnect structures 210 of the wafers 202 and 204) using at least one bonding process, rather than forming only one type of the bonds, as is the practice in other types of wafer-to-wafer or die-to-die bonding processes, for example.

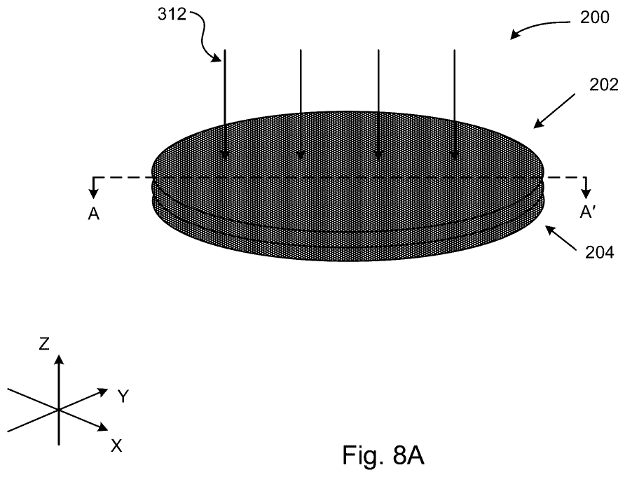

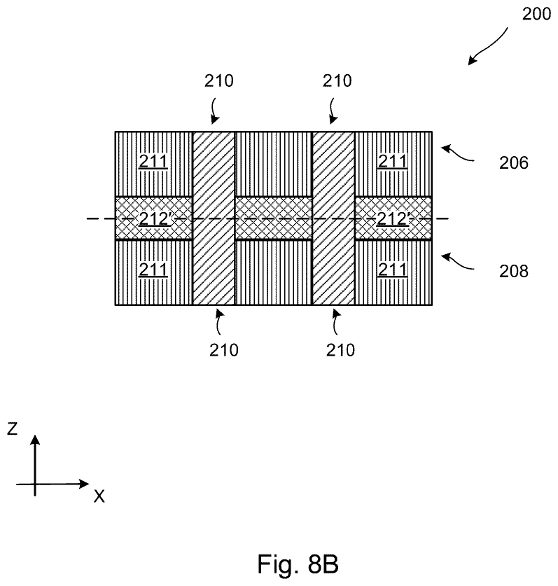

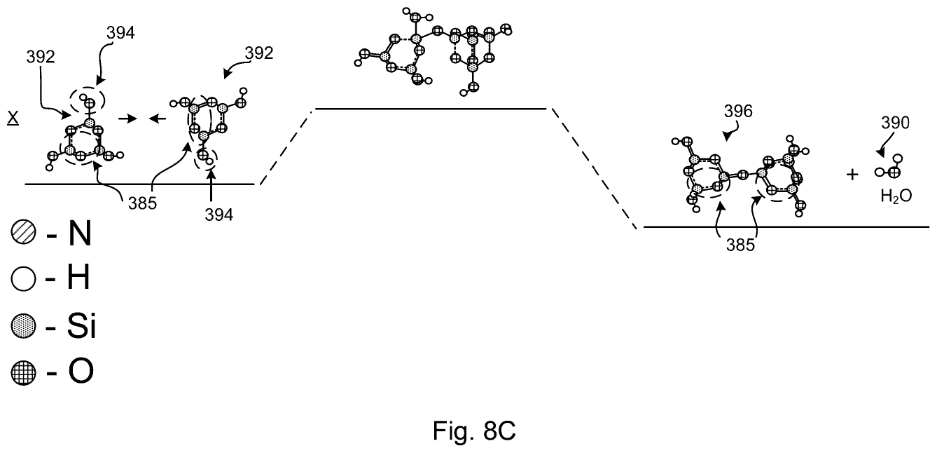

Referring to FIGS. 1A and 8A-8C, the method 100 at operation 110 performs a baking (or annealing) process 312 to heat the coupled wafers 202 and 204 using at least one suitable heat treatment process, such as rapid thermal processing (RTP). Heating the wafers 202 and 204 may expand the interconnect structures 210 to fill the trench 213 surrounded by the treated dielectric layer 212′. Hence, annealing the wafers 202 and 204 can increase a dimension (e.g., height) of the interconnect structures 210 to physically contact each other (e.g., through/via the trench 213), as depicted in FIG. 8B. In some instances, the interconnect structures 210 of the wafers 202 and 204 may expand to the same dimension. In some instances, the interconnect structures 210 may not include the same dimension after the expansion, such that the interconnect structures 210 extend to contact the other.

Referring to FIG. 8C, Scheme X demonstrates an example reaction occurring between the treated dielectric layer 212′ of the first surface 206 coupled to the treated dielectric layer 212′ of the second surface 208 during the baking process 312. In the present embodiments, the treated dielectric layer 212′ includes a compound 392 having —OH groups 394 bonded to —Si—O—Si— groups 385, where the —OH groups 394 of two molecules of the compound 392 react with each other to form a compound 396, thereby establishing chemical bonds between the first surface 206 and the second surface 208 and expelling H₂O 390 in the process. In this regard, by increasing the amount of hydroxide (i.e., the —OH groups 394) present at the surface of the treated dielectric layer 212′ (see FIG. 6B), the bonding (or coupling) capabilities between the first surface 206 of the first wafer 202 and the second surface 208 of the second wafer 204 may be enhanced. In the present embodiments, sequentially implementing the hydrogen plasma treatment 302, the oxygen plasma treatment 304, and the nitrogen plasma treatment 306 increases the extent of reaction between —OH groups 394, leading to a greater density of —Si—O—Si— groups 385 formed in the treated dielectric layer 212′ and enhanced chemical bonding between the wafers 202 and 204 as a result.

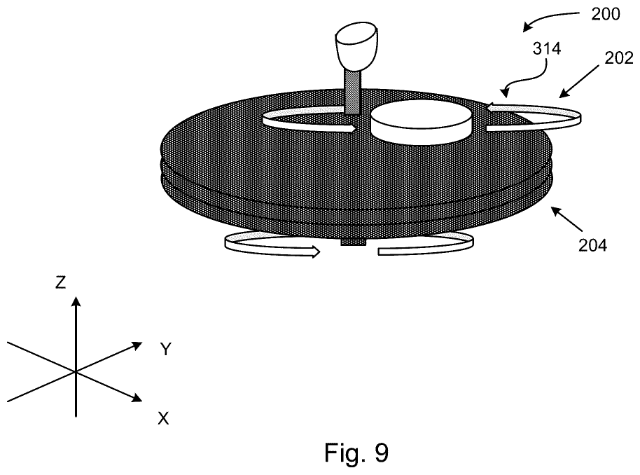

Referring to FIGS. 1A, 9, and 10, the method 100 at operation 112 performs additional operations to the semiconductor structure 200. For example, as depicted in FIG. 9, the method 100 at operation 112 may subject the wafers 202 and 204 to at least one thinning or etching process 314. The thinning process 314 may be performed on a backside of one or both of the wafers 202 and 204 before, during, or after merging the wafers. The thinning process 314 may be performed using at least one suitable etching technique, such as a chemical etching process.

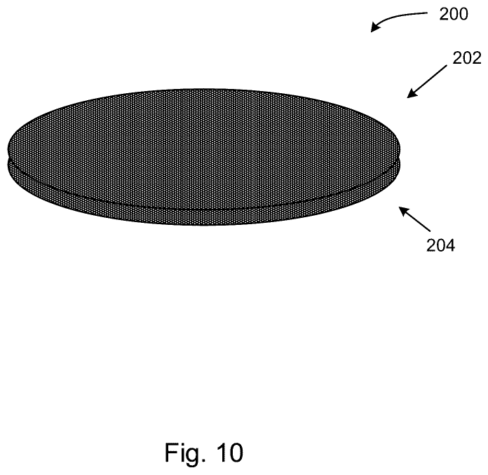

For example, the backside of the first wafer 202 may be etched or thinned using the at least one suitable etching technique. In some instances, the semiconductor structure 200 can be inverted, such that the second wafer 204 is the top wafer above the first wafer 202. In this case, the backside of the second wafer 204 may be etched. In some instance, the semiconductor structure 200 may not be inverted, and one or both of the wafers 202 and 204 may be etched. Etching the backside of at least one wafers 202 and 204 may reduce the overall dimension (e.g., thickness) of the semiconductor structure 200, as depicted in FIG. 10.

In some embodiments, after thinning the wafers 202 and 204, at least one suitable lithography technique, such as photolithography, can be performed on at least one of the wafers 202 and 204. For example, after bonding the various interconnect structures 210, thinning the wafers 202 and 204, among other fabrication procedures, one or more patterns can be formed in at least one of the first or second substrates, thereby enabling (e.g., electrical) connection with the interconnect structures 210, among other materials, of the wafers 202 and 204.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method of fabricating a semiconductor structure, comprising:
providing a first substrate having a first surface and a second substrate having a second surface, the first surface and the second surface each including a dielectric layer;
treating the first surface and the second surface, including:
performing a hydrogen plasma treatment to form hydrogen-terminated groups on the dielectric layer;
performing an oxygen plasma treatment to oxidize the dielectric layer with the hydrogen-terminated groups; and
performing a nitrogen plasma treatment to the oxidized dielectric layer to form a treated dielectric layer;
rinsing the first surface and the second surface to hydrolyze the treated dielectric layer; and
coupling the hydrolyzed and treated dielectric layer on the first surface with the hydrolyzed and treated dielectric layer on the second surface.

2. The method of claim 1, wherein the dielectric layer includes a silicon-containing dielectric material.

3. The method of claim 1, wherein the dielectric layer includes a carbon-containing group, a nitrogen-containing group, or both.

4. The method of claim 3, wherein the dielectric layer includes the carbon-containing group, and wherein performing the hydrogen plasma treatment forms the hydrogen-terminated groups that include —CH₂.

5. The method of claim 3, wherein the dielectric layer includes the nitrogen-containing group, and wherein performing the hydrogen plasma treatment forms the hydrogen-terminated groups that include —NH.

6. The method of claim 1, wherein performing the oxygen plasma treatment forms a volatile compound.

7. The method of claim 6, wherein the volatile compound includes HNO, CH₂O, or both.

8. A method of fabricating a semiconductor structure, comprising:
providing a first substrate having a first surface and a second substrate having a second surface, the first surface and the second surface each including a silicon-based dielectric layer;
applying hydrogen plasma to form hydrogen-terminated groups on the silicon-based dielectric layer;
applying oxygen plasma to oxidize the silicon-based dielectric layer including the hydrogen-terminated groups;
applying nitrogen plasma to the oxidized silicon-based dielectric layer, thereby forming a treated silicon-based dielectric layer;
rinsing the treated silicon-based dielectric layer; and
coupling the first substrate to the second substrate by physically contacting the rinsed and treated silicon-based dielectric layer on the first surface with the rinsed and treated silicon-based dielectric layer on the second surface.

9. The method of claim 8, wherein the silicon-based dielectric layer includes a carbon-containing dielectric material, a nitrogen-containing dielectric material, or both.

10. The method of claim 9, wherein the silicon-based dielectric layer includes silicon nitride (SiN), silicon carbonitride (SiCN), silicon oxide (SiO₂), silicon oxynitride (SiON), silicon oxycarbonitride (SiOCN), or combinations thereof.

11. The method of claim 9, wherein the hydrogen-terminated groups include —NH, —CH₂, or both.

12. The method of claim 8, wherein applying the oxygen plasma forms a first compound including —Si—O—Si— groups and a second compound including HNO, CH₂O, or both, in the oxidized silicon-based dielectric layer.

13. The method of claim 8, wherein applying the nitrogen plasma treatment forms —NO groups in the treated silicon-based dielectric layer.

14. The method of claim 13, wherein rinsing the first surface and the second surface includes reacting deionized water (DI H₂O) with the —NO groups in the treated silicon-based dielectric layer to form —OH groups.

15. The method of claim 14, wherein coupling the first substrate to the second substrate includes reacting the —OH groups in the hydrolyzed and treated dielectric layer of the first surface with the —OH groups in the hydrolyzed and treated dielectric layer of the second surface.

16. The method of claim 8, wherein coupling the first substrate to the second substrate further includes:
aligning the rinsed and treated silicon-based dielectric layer on the first surface to face the rinsed and treated silicon-based dielectric layer on the second surface;
physically contacting the aligned first surface and second surface; and
subsequently thinning the first substrate, the second substrate, or both.

17. The method of claim 8, wherein the first surface and the second surface each further include an interconnect structure disposed adjacent the dielectric layer, and wherein coupling the first substrate to the second substrate includes physically contacting the interconnect structure of the first surface with the interconnect structure of the second surface.

18. A method of fabricating a semiconductor structure, comprising:
providing a first substrate having a first surface and a second substrate having a second surface, the first surface and the second surface each including a dielectric feature;
applying surface treatment to the dielectric feature, including:
applying hydrogen plasma to form hydrogen-terminated groups on the dielectric feature;
applying oxygen plasma to oxidize the dielectric feature having the hydrogen-terminated groups;
applying nitrogen plasma to the oxidized dielectric feature, thereby forming a treated dielectric feature on the first surface and the second surface; and
hydrolyzing the treated dielectric feature; and
coupling the first substrate to the second substrate by physically contacting the hydrolyzed and treated dielectric layer on the first surface with the hydrolyzed and treated dielectric layer on the second surface.

19. The method of claim 18, wherein the hydrogen-terminated groups include —NH, —CH₂, or both.

20. The method of claim 18, wherein the first surface and the second surface each include a conductive feature adjacent the dielectric feature, and wherein coupling the first substrate to the second substrate further includes aligning the conductive feature of the first surface with the conductive feature of the second surface.
